(19) United States
(12) Patent Application Publication
(10) Pub. No.: US 2016/0333458 A1
(43) Pub. Date: Nov. 17, 2016

(54) SURFACE COATING WITH RARE EARTH METAL OXIDES

(71) Applicant: FRAUNHOFER-GESELLSCHAFT ZURFÖRDERUNG DER ANGEWANDTEN FORSCHUNG, München (DE)

(72) Inventors: Michael Haupt, Leinfelden-Echterdingen (DE); Christian Oehr, Herrenberg (DE); Jakob Barz, Stuttgart (DE)

(73) Assignee: Fraunhofer-Gesellschaft zur Förderng der angewandten Forshcung e.V., München (DE)

(21) Appl. No.: 15/026,550

(22) PCT Filed: Oct. 1, 2014
(86) PCT No.: PCT/EP2014/071049

§ 371 Date: Jul. 11, 2016

(30) Foreign Application Priority Data
Oct. 1, 2013 (DE) 10 2013 219 903.1

(51) Int. Cl. C23C 14/08; C23C 14/34; C23C 14/14

(52) U.S. Cl. CPC C23C 14/08; C23C 14/14; C23C 14/34

(57) ABSTRACT

The invention concerns a two- or three-dimensional body having an anti-ice coating comprising at least one rare earth metal oxide, a method for the production thereof, and the use of this anti-ice coating for preventing the formation of ice on, or for reducing the adherence of ice to, at least one surface of the two- or three-dimensional body or for lowering the freezing point.

### FIELD OF INVENTION

The present invention relates to a two- or three-dimensional body with an anti-icing coating comprising at least one rare earth metal oxide, to methods for the production thereof and to the use of this anti-icing coating for preventing the formation of ice on or for reducing the force of ice adhesion to at least one surface of the two- or three-dimensional body or for lowering the freezing point.

### BACKGROUND

It is known that ice affects the functional capability and safety of two- or three-dimensional bodies which, among others, include winter sports equipment, wind turbines, front windshields, rear window panes, and signal light coverings.

Where winter sports equipment is concerned, the ice, for example, adheres to ski bindings and, thus, impairs, for example, the release of the bindings in the event of a fall. For example, ice adheres to the upper side of skis so that, particularly, the formation of ice on touring skis or cross-country skis produces additional weight, additional resistance and less control of the ski. Ice that adheres to and forms on ski goggles affects the safety and wearing comfort, particularly, by limiting one's vision from outside on the one hand and, on the other hand, by the fact that the goggles steam up more easily inside when ice forms on or adheres to the ventilation holes. Finally, ice that adheres to and forms on the ski goggles means a loss in wearing comfort because the weight of the goggles increases and, in some circumstances, ice will come into contact with one's skin.

It is known that these problems can be prevented by structural geometrical adjustments, particularly, of ski bindings, for example, by special jaw systems in the front area of the binding. This is to prevent water, snow and ice from entering the hollow spaces of the binding. It is also known that ice adhesion can be prevented by means of flexible plastic coatings. The necessity to prevent water, snow or ice from entering safety-relevant areas of winter sports equipment therefore requires that the aforementioned special structural and geometrical measures should be implemented. On the one hand, such measures limit the given technical structural diversity but, on the other hand, also the degrees of freedom in the design of winter sports equipment. The use of anti-icing spray or wax may make a contribution to the solution of the aforementioned technical problems but only within a scope that is very limited in terms of time. Usually and depending on the frequency of use and on weather conditions, these agents must be applied repeatedly.

As is known, the use of wind turbines, which are also referred to as wind power stations, is subject to atmospheric effects and, accordingly, is characterized by frequent exposition to rain, condensate water or snow. Under corresponding environmental conditions, such precipitation accumulates on the rotor blades of a wind power station in the form of ice. Among others, the fact that the additional weight of the precipitation on the rotor blade may lead to an imbalance of the rotor, with the result that the wind turbine must be switched off frequently and/or will even be damaged as the case may be, turns out to be problematic. As a general rule, the developing ice crust causes an additional roughness of the surface of the rotor blade, with the result of additional wind noise. The changing rotation dynamics reduces the efficiency of the wind power station, resulting in losses of revenue which, beyond that, can also be affected by a downtime which may be required due to repair work if necessary. Ultimately, the precipitation, particularly the ice, may be hurled off into the environment and, thus, compromise the safety of the environment. A summary of the technical problems associated with the formation of precipitation on rotor blades of wind power stations can, for example, be found in Seifert and Tammelin, Final Report, Deutsches Windenergieinstitut Wilhelmshaven, JOU2-CT93-0366, DEWI 1996.

To solve the problems discussed above, the rotor blades are often heated from inside by means of electrical heater mats incorporated in the rotor blade, by hot air or by microwaves. To achieve this, sensors must be integrated into the rotor blade, which register the ice formation and switch the heater systems on and off.

To prevent the formation of ice on front windshields or rear window panes, these are, for example, electrically heated by very thin heating filaments. Where signal light coverings are concerned, elaborately fine wires are laminated into a film and glued into the lamp housing for heating purposes.

The functional capability and safety of winter sports equipment, wind power stations, front windshields, rear window panes and signal light coverings are therefore affected by the formation and adhesion of ice. So far, there are no known cost-effective and long-term solutions for ensuring the functional capability and safety of these two- or three-dimensional bodies.

What is more, Azimi et al. (Nature Materials, 2013, 12, 315-320) disclose that rare earth metal oxide ceramics are hydrophobic.

Boinovich et al. (Mendeleev Communication, 2013, 23, 3-10) disclose that super-hydrophobic coatings can prevent icing of surfaces as seen from a theoretical point of view.

The Jahrbuch Oberflächentechnik, 2011, Volume 67, Pages 184 to 191, additionally discloses anti-icing coatings which are produced using fluorine-containing monomeric gases according to the low-pressure plasma process.

The technical problem forming the basis of the present invention, hence, is the requirement to provide means which prevent or reduce the icing of two- or three-dimensional bodies, particularly obviate the aforementioned drawbacks and, more particularly, ensure long-term, more preferably permanent, and effective protection against icing, preferably in a cost-effective and easily providable manner. Particularly, the invention aims at providing a surface coating which reduces, more particularly prevents, the ice adhesion force and/or ice formation on surfaces of a two- or three-dimensional body in a particularly advantageous manner.

The present invention solves the basic technical problem by providing the teachings of the independent claims.

### BRIEF DESCRIPTION OF FIGURES

FIG. 1 shows a surface coating with line-pattern structuring.

FIG. 2 shows a dot pattern that can be used alternatively and consists of hydrophilic dots.

### BRIEF SUMMARY OF INVENTION

In one aspect, the present invention relates to a body comprising an anti-icing coating. In some embodiments, the body comprises an anti-icing coating applied to a surface of the body, wherein the anti-icing coating has a thickness of up to 500 nm and comprises at least one rare earth metal oxide.

In some embodiments, the anti-icing coating comprises a structuring of elevations in the form of a dot or a line pattern having a spacing of from 1 to 1000 micrometers between elevations.

In another embodiment, the anti-icing coating a) contains 15 to 45 atomic percent of a rare earth metal and b) 30 to 80 atomic percent of oxygen wherein each is determined according to an XPS analysis and in relation to the total atomic percentage of the anti-icing coating.

In some embodiment, the anti-icing coating is produced by means of a cathode sputtering process. In other embodiment, the anti-icing coating is produced by means of a low-pressure plasma process. In still other embodiment, the anti-icing coating is produced by means of a sol-gel plasma process.

In another aspect, the present invention relates to an anti-icing coating having a thickness of up to 500 nm, wherein the anti-icing coating comprises at least one rare earth metal oxide.

In another aspect, the present invention also relates to a method for the production of a coated body comprising an anti-icing coating applied to the surface of the body using a surface coating process, wherein an anti-icing coating having a thickness of up to 500 nm, comprises at least one rare earth metal oxide.

In one embodiment, the method comprise applying an anti-icing coating comprising

a) 15 to 45 atomic percent of at least one rare earth metal and

b) 30 to 80 atomic percent of oxygen wherein each is determined according to XPS analysis and in relation to the total atomic percentage of the anti-icing coating.

In another embodiment, the method comprises applying an anti-ice coating to a surface, comprising applying to a surface an anti-ice coating containing a) at least one rare earth metal and b) oxygen to prevent the formation of ice on at least one surface of a body.

In another embodiment, the method comprises applying an anti-ice coating to a surface, comprising applying to a surface an anti-ice coating containing a) at least one rare earth metal and b) oxygen to reduce the force of ice adhesion to at least one surface of a body.

In another embodiment, the method comprises applying an anti-ice coating to a surface, comprising applying to a surface an anti-ice coating containing a) at least one rare earth metal and b) oxygen to lower the freezing point of a liquid substance adhering to at least one surface of a body.

In another embodiment, the method comprises applying an anti-ice coating to a surface, comprising applying to a surface an anti-ice coating containing a) at least one rare earth metal and b) oxygen to slow down the freezing process of a liquid substance adhering to at least one surface of a body.

In some embodiments, the anti-icing coating applied has a thickness of 10 to 500 nm.

In other embodiments, the anti-icing coating applied has a thickness of 10 to 195 nm.

In some embodiments, the elevations in the form of a dot or line form recesses between the elevations, wherein the recesses have a dimension of from 1 to 1000 micrometers.

In some embodiments, the elevations in the form of a dot or line pattern have spacings between the elevations of from 0.01 to 800 nanometers.

In some embodiments, the elevations in the form of a dot or line form recesses between the elevations, wherein the recesses have a dimension of from 0.01 to 800 nanometers.

### DETAILED DESCRIPTION OF INVENTION

The present invention particularly relates to a two- or three-dimensional body, comprising an anti-icing coating that is applied to at least one surface of the two- or three-dimensional body and has a thickness of up to 500 nm, preferably of up to 195 nm, preferably from 10 to 500 nm, preferably from 10 to 195 nm, wherein the anti-icing coating comprises at least one rare earth metal oxide, preferably consists of at least one rare earth metal oxide.

Preferably, the anti-icing coating comprises at least one monomolecular layer, more preferably exactly one monomolecular layer of the at least one rare earth metal oxide.

The term “two-dimensional body” or “body” is understood to mean a body in a three-dimensional space having the spatial axes x, y and z, the body having the spatial extents x′, y′ and z′ along the spatial axes, wherein the spatial extents of x′ and y′ are in clear excess of the spatial extent z′, preferably by a factor of 5, preferably by a factor of 10, preferably by a factor of 50, preferably by a factor of 100, preferably by a factor of 1000. Accordingly, the term “two-dimensional body” is understood to mean that a certain spatial extent is achieved in each of the three spatial axes.

The atomic percents of the elements present in the anti-icing coating refer to the total atomic percentage of the anti-icing coating and sum up to 100 atomic percent of the total anti-icing coating.

In the context of the present invention, a “pattern” is understood to mean a consistent structure according to which the structuring feature, for example, a dot or a line, is repeated regularly. According to the invention, an arbitrary distribution of structuring elements does not represent a pattern.

The term “rare earth metal oxide” is understood to mean an oxide of the metals of rare earths. The group of metals of rare earths includes scandium, yttrium and the lanthanides, i.e., lanthanum, cerium, praseodymium, neodynium, promethium, samarium, europium, gadolinium, terbium, dysprosium, holmium, erbium, thulium, ytterbium, and lutetium. Preferably, the rare earth metal oxides can be represented by the general formula REₓO_{y} with x=1 to 6 and y=1 to 11, wherein RE stands for rare earth metal.

Preferably, the at least one rare earth metal oxide comprises a chemical composition that is selected from the group consisting of Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Er₂O₃, Tm₂O₃, Yb₂O₃, Lu₂O₃ and mixtures thereof.

A preferred embodiment of the present invention is the at least one rare earth metal oxide, selected from scandium oxide, yttrium oxide, lanthanum oxide, cerium oxide, praseodymium oxide, neodynium oxide, promethium oxide, samarium oxide, europium oxide, gadolinium oxide, terbium oxide, dysprosium oxide, holmium oxide, erbium oxide, thulium oxide, ytterbium oxide, lutetium oxide, and mixtures thereof.

In a preferred embodiment of the present invention, the at least one rare earth metal oxide is selected from the group consisting of praseodymium oxide, neodynium oxide, samarium oxide, europium oxide, gadolinium oxide, dysprosium oxide, holmium oxide, erbium oxide, thulium oxide, ytterbium oxide, lutetium oxide, terbium oxide, cerium oxide, and mixtures thereof.

In a preferred embodiment of the present invention, the anti-icing coating comprises at least one rare earth metal in metallic form and, most preferably, in particle form, in addition to the at least one rare earth metal oxide. Preferably, at least one rare earth metal and at least one rare earth metal oxide are contained in the anti-icing coating.

In a preferred embodiment of the present invention, the at least one rare earth metal oxide is selected from the group consisting of scandium oxide, yttrium oxide, lanthanum oxide, and mixtures thereof.

In a preferred embodiment of the present invention, the at least one rare earth metal oxide is scandium oxide, preferably Sc₂O₃.

In a preferred embodiment of the present invention, the at least one rare earth metal oxide is yttrium oxide, preferably Y₂O₃.

In a preferred embodiment of the present invention, the at least one rare earth metal oxide is lanthanum oxide, preferably La₂O₃.

In a preferred embodiment of the present invention, the at least one rare earth metal oxide is cerium oxide, preferably CeO₂.

In a preferred embodiment of the present invention, the at least one rare earth metal oxide is preseodymium oxide, preferably Pr₆O₁₁.

In a preferred embodiment of the present invention, the at least one rare earth metal oxide is neodymium oxide, preferably Nd₂O₃.

In a preferred embodiment of the present invention, the at least one rare earth metal oxide is promethium oxide, preferably Pm₂O₃.

In a preferred embodiment of the present invention, the at least one rare earth metal oxide is samarium oxide, preferably Sm₂O₃.

In a preferred embodiment of the present invention, the at least one rare earth metal oxide is europium oxide, preferably Eu₂O₃.

In a preferred embodiment of the present invention, the at least one rare earth metal oxide is gadolinium oxide, preferably Gd₂O₃.

In a preferred embodiment of the present invention, the at least one rare earth metal oxide is terbium oxide, preferably Tb₄O₇.

In a preferred embodiment of the present invention, the at least one rare earth metal oxide is dysprosium oxide, preferably Dy₂O₃.

In a preferred embodiment of the present invention, the at least one rare earth metal oxide is holmium oxide, preferably Ho₂O₃.

In a preferred embodiment of the present invention, the at least one rare earth metal oxide is erbium oxide, preferably Er₂O₃.

In a preferred embodiment of the present invention, the at least one rare earth metal oxide is ytterbium oxide, preferably Yb₂O₃.

In a preferred embodiment of the present invention, the at least one rare earth metal oxide is lutetium oxide, preferably Lu₂O₃.

In a preferred embodiment of the present invention, the anti-icing coating comprises at least two, preferably exactly two, preferably at least three, preferably exactly three rare earth metal oxides. In a preferred embodiment, the at least two rare earth metal oxides present in the anti-icing coating each form at least one layer inside the anti-icing coating. Preferably, the at least two rare earth metal oxides present in the anti-icing coating are distributed statistically. Preferably, the at least two different rare earth metal oxides form rare earth metal mixed oxides.

In a preferred embodiment, the anti-icing coating consists of the at least one rare earth metal oxide.

In a preferred embodiment, the anti-icing coating lowers the freezing point.

In a preferred embodiment, the anti-icing coating slows down the freezing process.

In a particularly preferred embodiment of the present invention, the structuring, particularly the structuring pattern, more particularly the dot or line pattern, is built up periodically.

Preferably, the two- or three-dimensional body comprises a structuring, wherein the structuring is irregular. Preferably, the two- or three-dimensional body comprises a rough or irregularly structured surface; more particularly, the rough or irregularly structured surface is achieved by means of an etching process.

Preferably, the present invention relates to a two- or three-dimensional body, comprising an anti-icing coating that is applied to at least one surface of the two- or three-dimensional body and has a thickness of up to 500 nm, preferably from 10 to 500 nm, wherein the anti-icing coating comprises a structuring, more particularly a topographic structuring, more particularly a structuring pattern, more particularly a structuring in the micrometer range, more particularly in the form of a dot or line pattern.

In a preferred embodiment, the present invention relates to a two- or three-dimensional body, wherein the anti-icing coating contains a) 15 to 45 atomic percent of at least one rare earth metal and b) 30 to 80 atomic percent of oxygen (each determined according to an XPS analysis (X-ray photoelectron spectroscopy) and in relation to the total atomic percentage of the anti-icing coating).

According to a preferred embodiment of the present invention, a two- or three-dimensional body is provided, comprising an anti-icing coating that is applied to at least one surface of the two- or three-dimensional body and has a thickness of up to 500 nm, preferably from 10 to 500 nm, preferably from 10 to 195 nm, containing 10 to 45 atomic percent of at least one rare earth metal oxide and 30 to 80 atomic percent of oxygen (each determined according to an XPS analysis (X-ray photoelectron spectroscopy) and in relation to the total atomic percentage of the anti-icing coating), wherein the anti-icing coating comprises a topographic structuring, particularly a structuring in the micrometer range, particularly a structuring pattern, more particularly a dot or line pattern.

The present invention solves the technical problem which is the basis thereof, particularly and in a preferred embodiment, by providing a two- or three-dimensional body, comprising an anti-icing coating that is applied to at least one surface of the two- or three-dimensional body and has a thickness of up to 500 nm, preferably from 10 to 500 nm, more preferably from 10 to 195 nm, containing, more preferably consisting of, a) 15 to 40 atomic percent of a rare earth metal, b) 30 to 70 atomic percent of oxygen and 5 to 25 atomic percent of other components, each determined according to an XPS analysis (X-ray photoelectron spectroscopy) and in relation to the total atomic percentage of the anti-icing coating, wherein this anti-icing coating comprises a structuring, particularly a topographic structuring, particularly a structuring pattern, particularly a dot or line pattern.

Below, such a particularly preferred embodiment of an anti-icing coating of the present invention will be referred to as a rare earth metal oxide coating.

In a particularly preferred embodiment, the other components of the rare earth metal oxide coating are selected from the group consisting of hydrogen, nitrogen, carbon and halogens, more particularly fluorine.

In a preferred embodiment, the anti-icing coating comprises a matrix in addition to the rare earth metal oxide, with the rare earth metal oxide being embedded in said matrix, preferably in particle form. This matrix comprises at least one hydrophobic material, preferably at least one hydrophobic polymer, preferably at least one fluorinated hydrocarbon polymer, preferably Teflon; preferably, the matrix consists of the at least one material, polymer or Teflon.

In this preferred embodiment, the anti-icing coating preferably comprises i) 1 up to 60 percent by weight, more preferably 1 to 40 percent by weight, more preferably 1 to 30 percent by weight, more preferably 1 to 20 percent by weight, 1 to 15 percent by weight, preferably 10 to 20 percent by weight of the at least one rare earth metal oxide, and ii) 40 to 99 percent by weight, preferably 60 to 99 percent by weight, preferably 70 to 99 percent, preferably 80 to 99 percent by weight, preferably 80 to 90 percent by weight of the matrix (each in relation to the total weight of the anti-icing coating).

Preferably, the present invention relates to a two- or three-dimensional body, wherein the anti-icing coating was produced utilizing a cathode sputtering process.

The term “cathode sputtering process”, also referred to as sputter deposition, is understood to mean a physical process in which atoms are ejected out of a solid body by being bombarded with high-energy ions, preferably with noble gas ions, and pass into the gaseous phase. Therein, the surface to be coated of the two- or three-dimensional body is, preferably, brought into the vicinity of the solid body, also referred to as target, from which the atoms are ejected for coating purposes, preferably in the form of ions, with the result that the atoms ejected from the target condense on the surface and form at least one layer. Preferably, this takes place in a process chamber in which the gas pressure is so low that the target atoms reach the surface without colliding with gas particles.

Preferably, the cathode sputtering process is selected from the group consisting of DC (direct current) sputters, HF (high frequency) sputters, ion beam sputters, magnetron sputters, and reactive sputtering. Preferably, the cathode sputtering process is magnetron sputtering, more preferably high power pulse magnetron sputtering.

In magnetron sputtering, atoms are removed from the target by bombarding a target with ions. These ions are generated by collisions between electrons and a sputter gas, which is also referred to as process gas, preferably argon.

According to this method, a magnetic field is, preferably, generated in the vicinity of the target, the magnetic field being aligned in parallel to the target, while an electric field is generated vertically thereto. Electrons in the vicinity of the target are, thus, forced to follow a helical path in the direction towards the target. As a result, the collisions between the electrons and the sputter gas and, therefore, the ionization force of the ions and the sputter rate are increased. Since more target material is sputtered, this results in a clearly higher coating rate at identical process pressure as compared with other cathode sputtering methods, such as DC sputtering and HF sputtering. In magnetron sputtering, the process pressure can, therefore, be up to a 100 times lower than that in other cathode sputtering processes, with the growth rates being the same. This results in a reduced spreading of the atoms ejected from the target on their path to the coated surface and, therefore, in a more compacted and, therefore, a less porous layer on the surface.

High power pulse magnetron sputtering is particularly advantageous because this method provides a more compacted layer morphology as well as an increased ratio of hardness to the E-module of the anti-icing coating as compared with conventional physical vapor deposition processes. In addition, this special method improves the adhesion of the anti-icing coating to the surface of the two- or three-dimensional body; particularly, the adhesion is doubled as compared with the physical vapor deposition processes known from the state-of-the-art. The method of high power pulse magnetron sputtering is known and, for example, disclosed in A. P. Ehiasarian, Journal of Applied Physics, 2007, 101(5), 054301.

Preferably, sputtering is carried out at a sputter rate of 30 to 80 nm per minute. Preferably, sputtering is carried out for a duration of 1 to 20 minutes. Preferably, the current rating is within a range from 0.1 to 1 ampere, preferably from 0.2 to 0.4 amperes. Preferably, the voltage is within a range from 300 to 500 V. Preferably, sputtering is carried out with a power being within a range from 100 to 400 watts.

Preferably, the coating applied to at least one surface of a two- or three-dimensional body, preferably by means of a cathode sputtering method, is retreated, more preferably oxidized further. Preferably, the follow-up treatment, more preferably the further oxidization, is achieved by thermal oxidation or by plasma oxidation.

In thermal oxidation, the coated surface is, preferably, treated at a temperature within a range from 100 to 700° C., more preferably from 200 to 500° C., more preferably from 300 to 400° C., in the presence of oxygen, more preferably in an oxygen atmosphere, more preferably together with water. Preferably, the duration of the follow-up treatment is 10 minutes to 24 hours, more preferably 30 minutes to 1 hour. Preferably, the follow-up treatment is carried out at a pressure of 0.01 bar to 1 bar, more preferably 0.1 to 0.5 bar. While thermal oxidation is in progress, the oxygen continuously, preferably, flows across the surface to be treated.

Preferably, plasma oxidation takes places using oxygen as plasma gas. Preferably, the plasma discharge is a microwave or radio frequency plasma discharge. During plasma oxidation, the temperature is, preferably, within a range between 0 to 400° C., more preferably 100 to 400° C. The oxygen is, preferably, fed into a plasma chamber, preferably at an O₂ flow of 25 to 500 sccm. Preferably, the power used during plasma oxidation is within a range between 100 and 3500 watts, more preferably from 150 to 300 watts. Preferably, the duration of the plasma oxidation is 10 to 30 minutes. Preferably, the pressure used during plasma oxidation is within a range between 0.001 and 0.5 bar, more preferably from 0.02 to 0.2 bar.

Preferably, the pure metal of the at least one rare earth metal, its hydroxides or oxides can be used as target. If the pure metal of the at least one rare earth metal is used, the ejection of the atoms from the target is, preferably, followed by an oxidation of the rare earth metal atoms, with the result that the corresponding rare earth metal oxide is formed. Likewise, a matrix comprising the at least one rare earth metal oxide can be used as target, wherein the matrix comprises, preferably consists of, at least one hydrophobic material, preferably at least one hydrophobic polymer, preferably at least one fluorinated hydrocarbon polymer, preferably Teflon.

In a preferred embodiment, the present invention relates to a two- or three-dimensional body, wherein the anti-icing coating was produced utilizing a low-pressure plasma process.

In a low-pressure plasma process, preferably metal-organic compounds of the at least one rare earth metal are used as a precursor, which is also referred to as a precursor compound, for the anti-icing coating. Preferably, the metal-organic compounds of the at least one rare earth metal are stable up to a temperature of 200° C. and, under the conditions that are usual in a plasma process, can be transferred into the gaseous phase up to a temperature of 200° C. Preferably, the metal-organic compounds are trialkyl compounds of the at least one rare earth metal, wherein the alkyl residues can be identical or different and are, preferably, selected from the group consisting of methyl, ethyl, propyl and butyl, more preferably methyl.

Such a process is known and is, for example, described by Haupt et al. in Plasma Process. Polym., (2008), 5, 33-43, and Vakuum in Forschung and Praxis, 17 (2005), No. 6, 329-335. Such a process is also described in WO 2007/012472 A1 and DE 10 2005 034 764 A1.

According to the invention, it is, preferably, provided in the low-pressure plasma process that the surface to be coated of the two- or three-dimensional body or the substrate to be coated is available in a gaseous atmosphere at low pressure, for example, at a pressure of <1 mbar, and process gases, for example, Ar, He, N₂ or O₂, as well as the appropriate starting material are, for coating purposes, used for the production of the rare earth metal coatings, for example, monomer gases, such as metal-organic compounds of the at least one rare earth metal, preferably trialkyl compounds of the at least one rare earth metal, wherein the alkyl residuals can be identical or different and are, preferably, selected from the group consisting of methyl, ethyl, propyl and butyl, preferably methyl.

Preferably, the gas molecules are ionized, fragmented and activated by igniting a high frequency plasma between two electrodes, for example, at 13.56 MHz, with the result that plasma is produced. Now, chemical reactions causing the plasma products to be covalently bound to the surface to be coated take place in the plasma phase or, rather, on the surface to be coated.

In a preferred embodiment, the coating of the two- or three-dimensional body can be made with an anti-icing adhesion property using a low-pressure plasma process, wherein a plasma is produced and rare earth metal oxide layers are applied to the elastic conduction element using a high-frequency discharge between at least two electrodes made of reactive gas which, for example, contains metal-organic compounds of the at least one rare earth metal, preferably trialkyl compounds of the at least one rare earth metal, wherein the alkyl residues can be identical or different and are, preferably, selected from the group consisting of methyl, ethyl, propyl and butyl, preferably, methyl.

In a preferred embodiment, the present invention relates to a two- or three-dimensional body, wherein the anti-icing coating was produced utilizing a sol-gel process.

According to the invention, the “sol-gel process” is understood to mean a method for the manufacture of non-metallic inorganic, hybrid polymeric or solid-body-like materials made of colloidal dispersions, the so-called sols. Preferably, sols are dispersions of solid particles of a size within a range from 1 nm to 100 nm. Preferably, precursor compounds are used in the sols. Gels, that are polymer-like or solid-body-like structures, are produced by hydrolysis and condensation of the precursor compounds. Subsequently, the gel is transferred into an oxide-ceramic material, i.e., into the anti-icing coating, preferably by means of a controlled heat treatment in the presence of air.

In a sol-gel process, metal-organic compounds of the at least one rare earth metal are, preferably, used as a precursor, which is also referred to as a precursor compound, for the anti-icing coating. Preferably, the metal-organic compounds of the at least one rare earth metal are stable up to a temperature of 200° C. and, under the conditions that are usual in a plasma process, can be transferred into the gaseous phase up to a temperature of 200° C. Preferably, the metal-organic compounds are trialcoholate compounds of the at least one rare earth metal, wherein the alcoholate residues can be identical or different and are, preferably, selected from the group consisting of methylate, ethylate, propylate and butylate, more preferably methylate.

Preferably, the rare earth metal oxide is obtained while the surface of the two- or three-dimensional body is coated or in a further process step subsequent to coating.

Particularly, the invention relates to an anti-icing coating having a thickness of up to 500 nm, preferably 10 to 500 nm, wherein the anti-icing coating comprises at least one rare earth metal oxide.

In a preferred embodiment, the statements made and/or the preferred embodiments associated with the anti-icing coating provided on the at least one surface of a two- or three-dimensional body are also applicable mutatis mutandis to the anti-icing coating as such.

In a particularly preferred embodiment, the anti-icing coating also comprises a structuring in the nanometer range in addition to the structuring in the micrometer range.

In a particularly preferred embodiment, the anti-icing coating is an anti-icing coating which comprises a structuring in the micrometer range and a structuring in the nanometer range, the latter being produced in a low-pressure plasma process.

In a particularly preferred embodiment, the anti-icing coating is an anti-icing coating which comprises a structuring in the micrometer range and a structuring in the nanometer range, the latter being produced in a sol-gel process.

The anti-icing coating according to the invention, which is applied to a surface of the two- or three-dimensional body is to advantage in that it reduces and/or slows down the formation of ice on the surface of the two- or three-dimensional body and, in a preferred embodiment, causes a lowering of the freezing point. The ice adhesion is reduced. Accordingly, the surface of the two- or three-dimensional body is protected against ice and snow. Advantageously, the anti-icing coating is constantly present on the surface of the two- or three-dimensional body so that, accordingly, its action is also constant.

Preferably, the at least one surface of the two- or three-dimensional body is provided with an optionally supported coating that is dirt-repellant and can easily be cleaned. In addition, the anti-icing coating according to the invention is resistant to abrasion and erosion—in contrast to polymeric coatings. Likewise, the anti-icing coating according to the invention has a high temperature stability, i.e., it is stable up to a temperature of 600° C., preferably of 500° C., preferably of 300° C.

In a preferred embodiment, the two- or three-dimensional body is designed as front windshield, rear window pane, side window pane, headlight covering, particularly for an LED headlight, preferably of a ship, a car, a train or an airplane.

Preferably, the two- or three-dimensional body is designed as a skylight for a house or for a motor vehicle.

Preferably, the two- or three-dimensional body is designed as a signal light or beacon of a ship, an offshore drilling platform or an offshore wind turbine.

Preferably, the two- or three-dimensional body is designed as a solar panel for photovoltaics or solar thermal energy.

Preferably, a film coated, structured and/or stamped with the anti-icing coating is used in the field of architecture, motor vehicles or on a rotor blade of a wind turbine, an airplane or a piece of sports equipment.

In a preferred embodiment, the present invention hence provides that the surface of a two- or three-dimensional body should be provided with an optionally supported coating which, on the one hand, reduces, more particularly prevents, an adhesion of ice and, on the other hand, lowers the freezing point of water, with the result that the water does not freeze on the surface or freezes on the surface only at a later point, i.e., at an even lower temperature.

Without wishing to be bound by theory, the freezing-point-lowering effect that is particularly preferred according to the invention results, on the one hand, from a topography or structuring in the nanometer range provided according to the invention, in combination with the quantitative and qualitative definition of the coating used according to the invention. Without being bound by theory, the freezing of a drop is slowed down or even prevented by the combination of these two technical aspects. Particularly, the specific roughness of the coating that is created according to the invention does not generate any crystal nuclei which have the suitable size for the formation of ice on the surfaces. A specific radius of exemplary surface clusters is not exceeded and the formation of ice, therefore, prevented. The aforementioned topography in the nanometer range is of a stochastic nature and is not defined by a mask. According to the invention, this structure in the nanometer range is, preferably, provided by utilizing a surface coating process, preferably selected from the group consisting of a cathode sputtering process, a sol-gel process and a plasma coating process, more particularly a low-pressure plasma coating process, more preferably by ion bombardment and polymerization. Without wishing to be bound by theory, the reduction in adhesion that is likewise observed according to the invention is improved by the surface structuring in the micrometer range. In a particularly preferred embodiment, the roughness Ra (mean roughness), preferably, is 0.2 nm to 22 nm on a scan scale of 2 to 2 micrometers (xy direction).

By selecting various process parameters, such as the type and quantity of the precursor compounds used, the temperature, the pressure and the treatment time, it is possible to produce very thin structures in the nanometer range, particularly nanostructured layers. These structures are only a few nanometers in size, but have an effect on the wetting properties and therefore also on the ice formation and anti-icing properties. If water is applied onto the surface of the film, it contracts to form a ball-shaped drop which is then repelled from the surface due to the only minimal interaction with the surface.

According to the invention, the coating used, preferably, results in a lowering of the freezing point, particularly of at least 3° C. This effect of what is called “surface-induced pre-melting” causes an ice nucleus to melt on a coating, particularly on a coated film, at 0° C.; freezing can only be observed at a temperature of at least −6° C. Hence, the bulk freezing point of the water is lowered by the presence of the anti-icing coating on the films and icing, therefore, made more difficult.

According to the present invention, it is, hence, provided that the at least one surface comprises a coating that has anti-ice adhesion properties. According to the invention, this is also referred to as anti-icing coating.

In the context of the present invention, anti-ice adhesion properties is understood to mean that the adhesion of ice on the external surface of the two- or three-dimensional body is very low, i.e., that the ice can be detached from this surface relatively easily.

Preferably, the anti-icing coating provided according to the invention is hydrophobic or oleophobic.

What is more, the anti-icing coating according to the invention is characterized by the provided structuring, particularly in the micrometer range, more particularly a two- or three-dimensional structuring.

In a preferred embodiment of the present invention, it is particularly achieved by the provided structuring in the form of a pattern, more particularly of a dot or line pattern, that drops that are forming or depositing on the surface to be coated to produce larger units are prevented from flowing together, i.e., from coalescing.

In a preferred embodiment, the structuring can be provided by the type of material, particularly by the hydrophilicity and/or ice adhesion, and/or a geometrical relief formation, more particularly a topographic structuring. In a particularly preferred embodiment, the provided structuring, particularly the topographic structuring, can provide a surface with a heterogeneous structure, particularly one that, in defined areas that are given by the line or dot pattern, causes a poorer or better ice adhesion than in other areas defined by the pattern, with the result that a different ice adhesion results on the surface, said ice adhesion resulting in breaking dots and, therefore, in a less stable ice adhesion process. Accordingly, the line pattern or the dot pattern can, for example, cause a poorer ice adhesion on the lines or dots of the surface. In a preferred embodiment, the line or dot pattern can consist of hydrophilic lines or dots and, therefore, cause an improved ice adhesion on the lines and dots; on the surface with the hydrophobic coating, this results in a systematic ice crystal growth in the hydrophilic areas, with the result that the non-connected ice crystals can, thus, break off more easily.

In a further embodiment, the dot or line pattern can be more hydrophobic than the anti-icing coating, therefore also resulting in a heterogeneous surface structuring.

In the context of the present invention, a structuring in the micrometer range is understood to mean a structuring, particularly a surface structuring, particularly a topographic structuring, the structures of which, for example, elevations or recesses or spacings between elevations or between recesses, comprise dimensions in the micrometer range, particularly dimensions from 1 to 1000 micrometers, preferably 10 to 900 micrometers, particularly 10 to 300 micrometers, particularly 10 to 200 micrometers, particularly 20 to 300 micrometers.

Such elevations can be present in the form of dots or lines. The dimensions of the structures can be extended in any direction, i.e., height, width, length, or relate to two or three of the mentioned alignments of the structure.

In the context of the present invention, a structuring in the nanometer range is understood to mean a structuring, particularly a surface structuring, particularly a topographic structuring, the structures of which, for example, elevations or recesses or spacings between elevations or between recesses, comprise dimensions in the nanometer range, particularly dimensions from 0.01 to 800 nm, particularly 0.1 to 700 nm, particularly 0.1 to 500 nm, particularly 0.1 to 100 nm, particularly 0.1 to 50 nm, particularly 0.1 to 40 nm, particularly 0.1 to 30 nm, particularly 0.02 to 50 nm, particularly 0.02 to 40 nm, particularly 0.02 to 30 nm, particularly 0.02 to 20 nm.

In a particularly preferred embodiment, a structuring, particularly a topographic structuring, particularly in the micrometer range, is understood to mean that the coating indicates a structure on its surface, for example, a three-dimensional structure, particularly in the form of recesses and/or elevations, particularly in the form of lines or in the form of dots. In a preferred embodiment, the three-dimensional structuring is, in addition, characterized by defined areas of different hydrophilicity and/or hydrophobicity or, rather, ice adhesion. The structuring can also represent a two-dimensional structuring, wherein the structure is, for example, produced by a different surface condition, for example, by defined areas of a different hydrophilicity and/or hydrophobicity or, rather, different ice adhesion, preferably in a dot or line pattern as well.

The procedure according to the invention, i.e., to provide a preferably hydrophobic and oleophobic coating of a surface of the two- or three-dimensional body, in combination with a structuring, particularly a topographic structuring, particularly a dot or line pattern, results in reduced water adhesion, reduced ice formation and/or reduced ice adhesion. The anti-icing coating provided according to the invention causes reduced ice adhesion, i.e., the ice can be torn off without residues to a large extent. Advantageously, the two- or three-dimensional bodies that are coated according to the invention can, therefore, be controlled more easily due to the reduced ice adhesion, comprise a lower weight and resistance and an improved safety, for example, an improved vision through ski goggles, an improved release of ski bindings, and the like.

In a particularly preferred embodiment, a structuring process is provided for making a structuring available, for example, a stamping process. In this preferred embodiment, the surface to be coated is, initially, structured, particularly stamped and, subsequently, coated with the anti-icing coating provided. As an alternative, the surface is, initially, coated with the anti-icing coating and, subsequently, structured, particularly stamped. In a further embodiment, it can be provided to coat the surface to be coated in parts only, for example, to cover said surface with at least one mask and make the coating, with the result that, in this case, the structuring process, i.e., the use of a mask during coating, takes place simultaneously with the coating itself.

In a particularly preferred embodiment, the anti-icing coating contains 15 to 45 atomic percent, preferably 20 to 45 atomic percent, preferably 30 to 40 atomic percent, of at least one rare earth metal and 30 to 80 atomic percent, preferably 35 to 70 atomic percent, preferably 40 to 65 atomic percent of oxygen (each determined according to an XPS analysis and in relation to the total atomic percentage of the anti-icing coating).

In a further preferred embodiment, the rare earth metal oxide anti-icing coating contains 5 to 25 atomic percent, preferably 10 to 20 atomic percent of other components.

In a particularly preferred embodiment, it is provided that the two- or three-dimensional body comprises the coating directly on its surface.

In a further preferred embodiment, it is provided that the two- or three-dimensional body comprises a supported coating of the type according to the invention, i.e., that the coating is applied to a surface of the two- or three-dimensional body by means of a substrate.

In a particularly preferred embodiment, the substrate can have a thickness of 0.003 to 0.300 mm, particularly 0.003 to 0.05 mm, particularly 0.150 to 0.300 mm, particularly 0.150 mm or 0.300.

In a particularly preferred embodiment, this substrate is a substrate made of conductive polymers, particularly inherently conductive polymers (ICP), polymers with a conductive coating or extrinsically conductive, i.e., filled, polymers which are, e.g., filled with carbon black, carbon nanotubes, graphs, metal fibers or soot, or a substrate made of lacquer or plastic, particularly polyurethane (PU), polyamide, polyimide, polycarbonate, PET (polyethylene terephthalate), PMMA (polymethyl methacrylate), PE (polyethylene), PP (polypropylene), ABS (acrylonitrile butadiene styrene) or PVC (polyvinyl chloride).

In a particularly preferred embodiment according to the invention, the substrate for the coating is a film that is, particularly, made of conductive polymers, particularly intrinsically conductive polymers (ICP), polymers with a conductive coating or extrinsically conductive, i.e., filled, polymers which are, e.g., filled with carbon black, carbon nanotubes, graphs, metal fibers or soot, or a substrate made of lacquer or plastic, particularly a plastic film made of PU, polyamide, polyimide, polycarbonate, PMMA, PET, PE, PP, ABS and/or PVC. Preferably, the plastic film is a self-adhesive plastic film. The substrates that are coated according to the invention, particularly plastic films, can be applied, e.g., glued or laminated (under temperature) to the surface of the two- or three-dimensional body to be coated. This is to advantage in that the films on the surfaces of the two- or three-dimensional body can be easily exchanged if they were exposed to large-scale wear and tear. According to the invention, the worn films are removed and replaced by new coated films to achieve this.

Preferably, the at least one surface to be coated of the two- or three-dimensional body comprises a reflecting coating, preferably a coating containing semiconductor metals and/or noble metals, preferably titanium.

In a further preferred embodiment, the substrate can also comprise a lacquer film, a lacquer foil or a lacquer coat, particularly having a thickness of 0.003 to 0.300 mm, particularly 0.003 to 0.050 mm, particularly 0.150 to 0.300 mm, particularly 0.150 mm or 0.300 mm

In a particularly preferred embodiment, the surface of the two- or three-dimensional body can be a plastic surface, a lacquer surface, a metal surface or a surface built up from composites. A plastic surface of the two- or three-dimensional body can, for example, be built up from PU, polyamide, polyimide, polycarbonate, PET, PE, PP, ABS or PVC. A metal surface can, for example, be built up from stainless steel, aluminum and/or magnesium. A lacquer surface can, for example, be a lacquer film or a lacquer coat.

In a particularly preferred embodiment, the anti-icing coating that is applied according to the invention to at least one surface of the two- or three-dimensional body either directly or by means of a substrate is characterized by an ice adhesion of ≦200 kPa, preferably <200 kPa, preferably ≦150 kPa, particularly ≦95 kPa, particularly <95 kPa.

In the context of the present invention, the ice adhesion is determined by an ice removal test. According to this ice removal test, water, particularly a water drop, is frozen to the surface for which the ice adhesion is to be determined. A cannula at which the frozen water drop can be torn off the surface is also frozen in the water, particularly the water drop. Subsequently, the drop is torn off the surface in vertical direction, with the force exerted being measured. The ice adhesion results from the quotient of force and surface (F/A, force/area).

In a particularly preferred embodiment, the coating has a maximum thickness of ≦200 nm, preferably <200 nm, preferably ≦195 nm, preferably ≦150 nm, preferably ≦100 nm, preferably ≦50 nm, in particular <50 nm.

In a further preferred embodiment, the anti-icing coating has a minimum thickness of a monomolecular layer of the at least one rare earth metal oxide, preferably ≧5 nm, particularly ≧10 nm, particularly ≧20 nm, particularly ≧25 nm.

In a preferred embodiment, the anti-icing coating has a thickness of 10 to 200 nm, preferably 10 to 195 nm, preferably 20 to 100 nm, preferably 25 to 50 nm.

In a particularly preferred embodiment, the water contact angle, i.e., the advance and retraction contact angles of water on the anti-icing coating each are >80′; preferably, both angles are >100° preferably >115°, preferably >120°, preferably >125°, preferably >130°, preferably >125°, preferably >130°, preferably >135°, preferably >140°, preferably >145°, preferably >150°, preferably >155°, preferably >160°, preferably >165°, preferably >170°, preferably >175°, preferably without the anti-icing coating comprising a structuring, preferably a structuring in the micrometer and nanometer ranges, preferably in the form of a line and dot pattern.

In a particularly preferred embodiment, the water contact angle, i.e., the advance and retraction contact angles of water on the anti-icing coating each are less than 120°, preferably less than 110°, preferably less than 100°, preferably less than 90°, preferably less than 80°.

Preferably, the anti-icing coating has a transmission of more than 70%, preferably more than 80%, preferably more than 90%, preferably more than 95% (in relation to the irradiated radiation in the visible range, i.e., in a range from 350 to 700 nm).

Preferably, the anti-icing coating reaches transmission values of more than 70% after it has been retreated.

Without wishing to be bound by a theory, a heterogeneous nucleation of ice takes place on the surface of the two- or three-dimensional body, wherein the surface serves as a nucleus for the formation of ice. The energy barrier of heterogeneous nucleation, also referred to as WHET, is always smaller than the energy barrier of homogeneous nucleation, also referred to as WHOM. These two energies are connected via a function F(CW), with CW being the contact angle. The greater the contact angle, the greater the function F(CW). It can surprisingly be concluded that preferably high contact angles are required to achieve a delay in ice formation (ice premelting effect).

Furthermore, the nano-roughness of the coating should be set such that a specific size of the nucleus on the surface will not be exceeded. In this case, water is neither able to crystallize.

By increasing the contact angle, the contact area of the water drop and/or the ice becomes smaller, whereby adhesion is also reduced (“Cassie-Baxter model”).

Preferably, the reduction in adhesive force takes place by a reduction of the van der Waals force and the electrostatic forces.

Apart from that, the rare earth metal oxide coating according to the invention causes the heat transmission from the drop, preferably the water drop, to the cold substrate to be reduced. Accordingly, the drop, preferably the water drop, remains liquid because it cannot discharge its crystallization energy.

In the context of the present invention, the water contact angle and the surface energy are, preferably, determined according to a) Müller, M. & Oehr, C., Comments on ‘An Essay on Contact Angle

Measurements’ by Strobel and Lyons. Plasma Processes and Polymers 8, 19-24 (2011), b) Gao, L. & McCarthy, T. J. How Wenzel and Cassie Were Wrong. Langmuir 23, 3762-3765 (2007), c) Blake, T. D. The physics of moving wetting lines. Journal of Colloid and Interface Science 299, 1-13 (2006) or d) Morra, M., Occhiello, E. & Garbassi, F. Knowledge about polymer surfaces from contact angle measurements. Advances in Colloid and Interface Science 32, 79-116 (1990).

Preferably, the XPS analysis is performed according to Surface Analysis by Auger and X-Ray Photoelectron Spectroscopy Edited by David Briggs and John T. Grant, ISBN 1-901019-04-7, Published in association with IM Publications.

In a particularly preferred embodiment, the anti-icing coating has a surface energy of <170 mJ/m, preferably <100 mJ/m, preferably <30 mJ/m, particularly ≦30 mJ/m, particularly ≦21 mJ/m, particularly <21 mJ/m.

In a particularly preferred embodiment, the two- or three-dimensional body is a winter sports equipment, preferably a ski, ski goggles, a snowboard or a ski helmet. In a further preferred embodiment, one surface of the ski is the surface of the ski edge, the top ski side, the ski binding, the brake arm, the release mechanics and/or the ski bearing plate.

In a particularly preferred embodiment, the top ski side is not the bottom ski side, i.e., not the ski bearing surface. In a further preferred embodiment, a surface of the ski goggles is the surface of the support area on the visual field, the pane ventilation, the visual field, the frame of the goggles and/or the head band.

In a further preferred embodiment, the dot or line pattern has a periodicity P with spacings in a range from 1 to 1000 micrometers, 10 to 900 micrometers, particularly 10 to 300 micrometers, preferably 10 to 200 micrometers, e.g., of 20 micrometers, 40 micrometers, 80 micrometers, 100 micrometers, 120 micrometers, 140 micrometers or 180 micrometers.

The periodicity is understood to mean the spacing of the dots or lines in relation to each other.

In a further preferred embodiment, the winter sports equipment has a periodicity P with spacings in a range from 1 to 1000 micrometers, 10 to 900 micrometers, particularly 10 to 300 micrometers, preferably 10 to 200 micrometers, e.g., of 20 micrometers, 40 micrometers, 80 micrometers, 100 micrometers, 120 micrometers, 140 micrometers or 180 micrometers.

According to a further preferred embodiment of the present invention, the diameter of the dots of the dot pattern is 1 to 1000 micrometers, 10 to 900 micrometers, particularly 10 to 200 micrometers, e.g., 20 micrometers, 40 micrometers, 80 micrometers, 100 micrometers, 120 micrometers, 140 micrometers or 180 micrometers.

In a particularly preferred embodiment, it is furthermore provided that the surface structuring, particularly the topographic surface structuring, particularly the dot or line pattern, is applied by means of a structuring process, for example, by stamping the substrate, e.g., film stamping, particularly prior to coating. Subsequently, the finished stamped film is coated. According to the invention, it is also possible to partially coat and, thus, structure the substrate, e.g., a non-stamped film, for example, to structure and coat the substrate, e.g., the film by using masks during coating.

In a preferred embodiment, it is therefore provided to apply the dot or line pattern according to the invention by film stamping.

In a further preferred embodiment, it is provided to apply the dot or line pattern to non-stamped substrates, particularly films, by using masks during coating, with the result that structuring and coating take place at the same time.

If supported coatings, particularly film-supported coatings, are used, it can be provided in a particularly preferred embodiment to coat the films continuously, for example rollwise, for example roll by roll, or in a batch process.

The present invention particularly relates to a method for the production of a coated two- or three-dimensional body, wherein the anti-icing coating is applied to the surface of the two- or three-dimensional body with a thickness of up to 500 nm, preferably from 10 to 500 nm, in a surface coating process. Preferably, the surface coating process is selected from the group consisting of cathode sputtering process, plasma process and sol-gel process, wherein the plasma process is an atmospheric or low-pressure plasma process.

Preferably, the present invention relates to a method wherein the anti-icing coating comprises a) 15 to 45 atomic percent of at least one rare earth metal and b) 30 to 80 atomic percent of oxygen (each according to an XPS analysis and in relation to the total atomic percentage of the anti-icing coating).

The invention also relates to a method for the production of a coated two- or three-dimensional body according to the present invention, wherein a preferably freezing-point-lowering anti-icing coating is applied to the surface of the two- or three-dimensional body with a thickness of up to 500 nm, preferably from 10 to 500 nm, in a surface coating process, with a structuring, particularly a surface structuring in the micrometer range being inserted into the surface.

If, in a further embodiment, the anti-icing coating, particularly the rare earth metal oxide coating, is not directly applied to the winter sports equipment but is provided on a substrate and is applied to the two- or three-dimensional body by means of a substrate, the anti-icing coating is initially applied to the substrate, then the structuring is inserted there and subsequently the thus supported anti-icing coating is applied to the two- or three-dimensional body.

According to the invention, a method for the production of a coated two- or three-dimensional body according to the present invention is also provided, wherein a coated substrate, particularly a coated film, preferably a plastic film, comprising a preferably freezing-point-lowering anti-icing coating having a thickness of up to 500 nm, preferably from 10 to 500 nm, containing 15 to 45 atomic percent of at least one rare earth metal and 30 to 80 atomic percent of oxygen (each according to an XPS analysis) is applied and fixed, e.g., glued, to a surface, particularly to an outside surface of a two- or three-dimensional body with a structuring, particularly in the form of a dot or line pattern, particularly comprising an anti-icing coating of the present invention.

According to the invention, it can be provided in a particularly preferred embodiment to provide the structuring separately from the coating, i.e., for example to structure a substrate by stamping and subsequently to make a complete or partial coating of the structured surface. It is also preferred according to the invention to initially make a coating of a surface and to structure, e.g., stamp the same subsequently. In a further embodiment, it can also be provided to make the structuring and the coating at the same time, for example, by partially coating the surface, e.g., using masks, i.e., that certain areas of the surface are excluded from coating, with the result that a structuring and a coating are formed at the same time.

The present invention also relates to the use of a coating, containing a) at least one rare earth metal and b) oxygen to prevent the formation of ice on at least one surface of a two- or three-dimensional body.

The present invention also relates to the use of a coating, containing a) at least one rare earth metal and b) oxygen to reduce the adhesion of ice to at least one surface of a two- or three-dimensional body.

The present invention also relates to the use of a coating, containing a) at least one rare earth metal and b) oxygen to lower the freezing point of a liquid substance, preferably water, adhering to at least one surface of a two- or three-dimensional body.

The present invention also relates to the use of a coating, containing a) at least one rare earth metal and b) oxygen to slow down the freezing process of a liquid substance, preferably water, adhering to at least one surface of a two- or three-dimensional body.

Preferably, the term “freezing point lowering” is understood to mean a physical process in which the freezing point of the liquid substance, preferably the water, is lower than under standard conditions, i.e., at a pressure of 1013 mbar. In the context of the present invention, the freezing point of the liquid substance, preferably the water, is accordingly lowered when the freezing point of the liquid substance, preferably the water, is lower than the freezing point prevalent under standard conditions. In the case of water, this means that the freezing point is lowered when the water freezes at a temperature of less than 0° C. According to the invention, freezing point lowering is preferably achieved when the liquid substance, preferably the water, preferably a water drop, freezes at a temperature that is lower than on a surface of a two- or three-dimensional body having no coating according to the invention or being preferred according to the invention and containing at least one rare earth metal and oxygen by at least 1° C., preferably by at least 2° C., preferably by at least 5° C., preferably by at least 10° C.

In the context of the present invention, the technical effect of “freezing slowing down” is achieved when, by coating at least one surface of a two- or three-dimensional body at a surface temperature of −20° C., the time period from the point when a drop of a liquid substance, preferably water, is applied to this surface until the drop crystallizes, i.e., freezes, is extended, preferably by at least a factor of 2, preferably by at least a factor of 5, preferably by at least a factor of 10, preferably by at least a factor of 20, as compared with such a surface of the two- or three-dimensional body having no coating according to the invention or being preferred according to the invention and containing at least one rare earth metal and oxygen.

Preferably, the present invention also relates to the use of a coating, preferably of an anti-icing coating, containing a) 15 to 45 atomic percent of at least one rare earth metal and b) 30 to 80 atomic percent of oxygen (each according to an XPS analysis and in relation to the total atomic percentage of the anti-icing coating), for coating at least one surface of a two- or three-dimensional body, to prevent the formation of ice on the at least one surface of the two- or three-dimensional body.

Preferably, the present invention also relates to the use of a coating, preferably of an anti-icing coating, containing a) 15 to 45 atomic percent of at least one rare earth metal and b) 30 to 80 atomic percent of oxygen (each according to an XPS analysis and in relation to the total atomic percentage of the anti-icing coating), for coating at least one surface of a two- or three-dimensional body, to reduce the force of ice adhesion to the at least one surface of the two- or three-dimensional body.

Preferably, the present invention also relates to the use of a coating, preferably of an anti-icing coating, containing a) 15 to 45 atomic percent of at least one rare earth metal and b) 30 to 80 atomic percent of oxygen (each according to an XPS analysis and in relation to the total atomic percentage of the anti-icing coating), for coating at least one surface of a two- or three-dimensional body, to lower the freezing point, preferably of water, preferably by at least 3° C., preferably by 6° C., as compared with the freezing point of water at 0° C.

Preferably, the present invention also relates to the use of a coating, preferably of an anti-icing coating, containing a) 15 to 45 atomic percent of at least one rare earth metal and b) 30 to 80 atomic percent of oxygen (each according to an XPS analysis and in relation to the total atomic percentage of the anti-icing coating), for slowing down the freezing process of a liquid substance, preferably water, adhering to at least one surface of a two- or three-dimensional body.

In a preferred embodiment, the statements made and/or the preferred embodiments associated with the anti-icing coating provided on at least one surface of a two- or three-dimensional body are also applicable mutatis mutandis to the use of the anti-icing coating.

Further advantageous embodiments of the invention result from the subclaims.

The invention will be illustrated in more detail by means of the available figures.

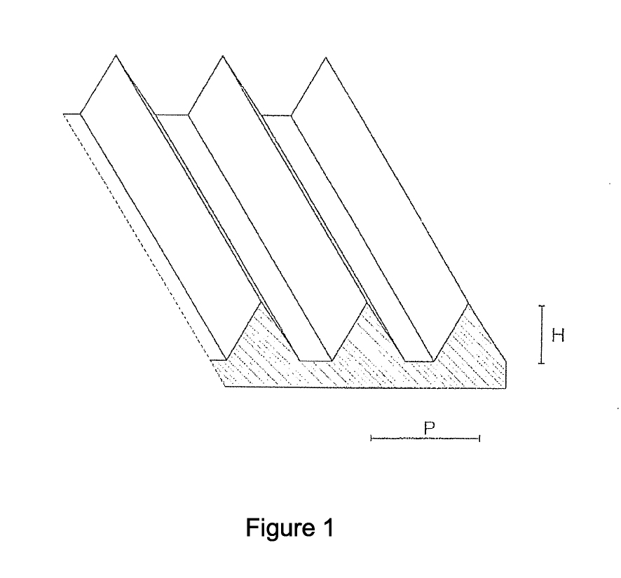

FIG. 1 shows a surface coating with line-pattern structuring. The ice adhesion achieved with the line pattern is particularly poor. The diagram shows the periodicity P and the structure height H with a periodicity P of 20, 40, 80, 100, 120, 140 or 180 micrometers and a structure height H of 20, 40, 80, 100, 120, 140 or 180 micrometers (Cassie-Baxter-model (heterogeneous wetting)).

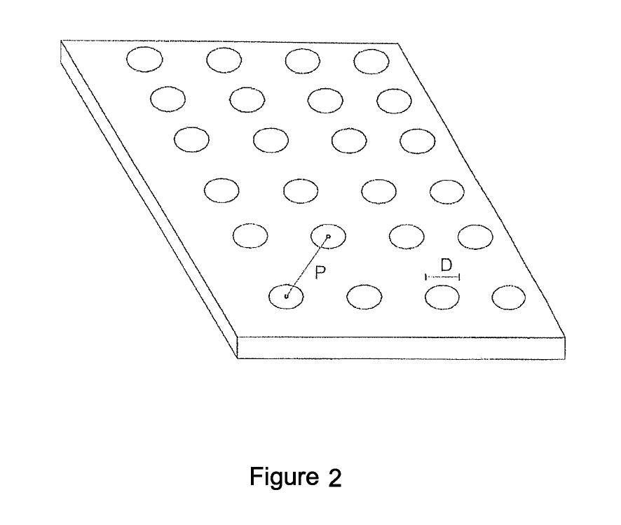

FIG. 2 shows a dot pattern that can be used alternatively and consists of hydrophilic dots having a contact angle of <10°, which achieves a specific ice crystal growth at the defined dots on the hydrophobic surface with the anti-icing coating, with the result that the ice crystals forming there and not being connected to each other can be more easily torn off by the slipstream. Preferably, the periodicity P=20, 40, 80, 100, 120, 140 or 180 micrometers. The diameter D of the hydrophilic dots can be 20, 40, 80, 100, 120, 140 or 180 micrometers.

### Examples

### 1. List of the Substrates Used

| Substrates | Manufacturer | Description |
|---|---|---|
| Object slides | Thermo Scientific, | 72.2% SiO₂, |
| | Germany | 14.3% Na₂O, |
| | | 6.4% CaO |
| | | Precleaned/ |
| | | ready for use |
| Microscope cover glass | Chance Propper Ltd., | — |
| | England | |
| Polycarbonate | Arla Plast, Sweden | |
| (Makroclear ®) | | |
| Silicon wafer | Malaster Company, | Crystal |
| | Inc., USA | orientation |
| | | <100> |
| PU film | Klebetechnik GmbH, | Microstructured |
| | Germany | surface with |
| | | cylindrical |
| | | patterns |

### 2. Generation of Cylindrical Patterns on PU Films

The PU films are stamped in a laboratory multi-platen press of type LabEcon 150 by Fontijne Grotnes. To achieve this, the polymer films are placed on the bottom plate which has been preheated to 85° C. beforehand. Prior to being subjected to a closing force of 150 kN, the female molds are positioned on the polymer films with their front side facing down. These conditions are then kept for 4 minutes, and subsequently the stamped films and the stamps are removed from the hot plates in order to prevent the films having an excessively long contact with high temperatures and, thus, to reduce the risk of hardening and changes in the mechanical properties. The stamped films are analyzed using the laser scanning microscope, with measurements of the cylindrical structures being summarized in Table 1.

TABLE 1

| Structured | Upper diameter | Basic diameter | Height | Spacing |
|---|---|---|---|---|
| PU film | [μm] | [μm] | [μm] | [μm] |
| A4 | 24.3 ± 1.1 | 34.0 ± 2.1 | 18.0 ± 1.4 | 49.8 ± 0.8 |
| A5 | 31.7 ± 2.4 | 46.1 ± 2.1 | 28.5 ± 0.1 | 123.2 ± 3.1 |
| A6 | 22.3 ± 9.3 | 53.8 ± 1.4 | 65.9 ± 2.9 | 276.5 ± 2.1 |

### 3. Magnetron Sputtering

A holmium layer is applied to various substrates at room temperature in a self-built direct-current magnetron sputter reactor. Therein, a holmium target is used as cathode. The substrates are locked in position on the substrate holder by means of polyimide adhesive tape. Optionally, a primary titanium layer is deposited on the substrate before the holmium layer; to achieve this, a titanium target is used as a second cathode and the receiver that is initially oriented towards the titanium target is rotated towards the Ho target after the deposition of the primary titanium layer has been completed. Using a combination of a rotary vane pump and a turbomolecular pump, the chamber is pumped down until the pressure has fallen down below a value of 1×10-6 mbar. Table 2 shows an overview of the targets used.

TABLE 2

| Target | Manufacturer | Use |
|---|---|---|
| Holmium | FHR Centrotherm Group | Deposition of the upper layer |
| Titanium | FHR Centrotherm Group | Optional deposition of the |
| | | intermediate layer |

Therein, the voltage may vary in order to achieve a constant current rating after a ramp time of 30 sec. In order to reduce an arcing flashover and to generate uniform glowing, the argon pressure is initially set to 8 μbar and then reduced to 6 μbar, wherein the sample is rotated away from the target. After a stable glow discharge has been reached, the sample is rotated towards the target and is exposed for the given net sputtering time. The distance between the target and the sample is 78 mm and is kept constant.

To calibrate the sputter rate, an aluminum foil of 2×2 mm and an object slide were weighed prior and subsequent to sputtering. Therein, the average thickness of the deposited film, dHo, is determined gravimetrically.

A linear correlation between the deposited layer thickness and the current rating as well as the sputtering time can be observed. Table 3 shows the preliminary trials with use being made of a holmium target at different current ratings, net sputtering times and surface pre-treatments, as well as the effects thereof on the appearance of the deposited layer. The voltage and power settings are 450 V and 0.27 kW, respectively.

TABLE 3

| | | | Sputtering | Film | Sputter | |
|---|---|---|---|---|---|---|
| | Surface | | time | thickness | rate | Remarks on the |
| Trial | pretreatment | I [A] | [min] | [nm] | [nm/min] | deposited film |
| 1 | None | 0.4 | 4 | 287 ± 5 | 72 ± 2 | Surface reflecting, |
| | | | | | | opaque, stripe pattern on |
| | | | | | | PC |
| 2 | Cleaned with | 0.2 | 1 | 34 ± 1 | 34 ± 1 | Surface reflecting, semi- |
| | isopropanol, dried | | | | | transparent, stripes (signs |
| | with compressed N₂ | | | | | of dried isopropanol), film |
| | | | | | | slightly matt on PC, |
| | | | | | | smudgy |
| 3 | Cleaned with | 0.2 | 1 | 34 ± 1 | 34 ± 1 | Same as in trial 2, film |
| | isopropanol, dried | | | | | less matt on PC, however, |
| | with compressed N₂, | | | | | less reflecting as |
| | activated with Ar | | | | | compared with the sample |
| | plasma (P_{Ar} = 6 μbar; | | | | | or trial 1 |
| | t = 1 min; P = 40 W) | | | | | |
| 4 | Activated with Ar | 0.2 | 1.5 | 58 ± 2 | 39 ± 2 | Surface reflecting, semi- |
| | plasma (P_{Ar} = 6 μbar; | | | | | transparent, stripe pattern |
| | t = 1 min; P = 40 W) | | | | | on PC, fine particles |
| | | | | | | (dust) on the surface |

The parameters of trial 4 are applied to make samples for the following experiments. The sputter rate of titanium was obtained from the previous calibration and is 7 nm/min at 0.2 A. Approx 25 nm of the intermediate titanium layer are deposited with the same current rating, voltage and power settings as in trial 4 in Table 3, as far as applicable.

### 4. Follow-Up Treatment

Cover glasses coated with holmium and silicon wafers are used in the following treatments after the deposition.

### 4.1 Thermal Oxidation

An oven model N 7/H by Nabertherm GmbH is used to treat the coated substrates at increased temperatures in an oxygen environment. The substrates are transferred into a quartz tube which is closed with an O-ring at its window to which the gas inlet and gas outlet as well as the cooling system are connected. Initially, the quartz tube is primed with argon gas to expel the atmospheric gases and remove undesired reactive and inflammable substances, and is then primed with oxygen. The wet oxidation process is carried out by means of a pearling system with inflow of oxygen and outflow of a mixture containing water vapor and oxygen. The water in the bottle is kept at a temperature of approximately 95° C. Table 4 shows a summary of the parameters of the thermal oxidation experiments. The heating rate of the oven is 5° C./min

TABLE 4

| Exper- | Suffix on the sample | |
|---|---|---|
| iment | Temperature - holding time | Gas supply |
| 1 | 100° C. - 24 h | Quartz tube primed with O₂ |
| | | for 3 min prior to heating |
| 2 | 100° C. - 24 h | Quartz tube primed with a |
| | (wet) | mixture containing O₂ and |
| | | water vapor for 3 min prior |
| | | to heating |
| 3 | 300° C. - 30 min | Continuous flow of a mixture |
| | (continuous flow, wet) | containing O₂ (0.2 bar) |
| | | and water vapor throughout |
| | | the entire glowing process |
| 4 | 400° C. - 30 min | Continuous flow of O₂ (0.2 bar) |
| | (continous flow) | throughout the entire glowing |
| | | process |
| 5 | 400° C. - 30 min | Quartz tube primed with O₂ |
| | | for 3 min prior to heating |
| 6 | 500° C. - 30 min | Quartz tube primed with O₂ |
| | | for 3 min prior to heating |
| 7 | 700° C. - 30 min | Quartz tube primed with O₂ |
| | | for 3 min prior to heating |

### 4.2 Plasma Treatment

In addition to the thermal treatment in the oven, treatments are carried out after deposition in oxygen plasmas which are produced by:

Microwave discharge (MW)

Radio-frequency discharge (RF)

Table 5 shows a summary of devices and treatment parameters.

| Devices | Description | Parameters |
|---|---|---|
| MW plasma | Tepla 300 (commer- | Pressure chamber = 0.2 mbar |
| reactor | cially available | Temperature = room temperature |
| | device by Technics | (RT) |
| | Plasma GmbH, | O₂ flow = 25 sccm |
| | Germany), | Power = 500 W |
| | f = 2.4 GHz | Duration = 30 min |
| Size A3 | Self-built with a | Chamber pressure = 0.02 mbar |
| Radio- | 13.56-MHz radio- | Temperature = RT |
| frequency | frequency generator | O₂ flow = 50 sccm |
| plasma | by Dressler Cesar | Power = 150 W |
| reactor | | Duration = 30 min |
| Radio- | Self-built with a | Chamber pressure = 0.006 mbar |
| frequency- | 13.56-MHz radio- | Temperature = RT; 200° C.; 400° C. |
| driven ICP | frequency generator | O₂ flow = 500 sccm |
| reactor | by Dressler Cesar | Power = 3500 W |
| | | Duration = 10 min |

Once the defined temperature has been reached, the reactor chambers are pumped down until the pressure falls to the given value. The radio-frequency power is transmitted to the electrode through an appropriate network which adjusts the impedance of the plasma to that of the generator, with the result that the power reflected by the matchbox to the electrode is only minimal or, in ideal cases, even absent. In this manner, a stable discharge is achieved. The setup of the self-built reactors is completed by gas and pressure controls.

### 5. Characterization and Analytics

### 5.1 X-Ray Photoelectron Spectroscopy) (XPS)

This technique which uses incident photons is applied to analyze the coated surfaces with regard to their composition and their chemical condition. For this purpose, use is made of the Axis Ultra Instrument by Krato Analytical Ltd. with an X-ray source of a monochromatic AlKα (1486.6 eV) line. The sample is exposed to the X-ray source under ultra-high vacuum conditions, and the emitted electrons are analyzed. The angle of radiation is 90°. The chemical and element composition originates from a layer close to the surface, which has a thickness of up to 10 nm.

In order to examine the variations in the chemical composition with increasing depth, spectra of a Ho layer on Si wafers are recorded as deposited at different sputter intervals. The in-situ bombardment with Ar⁺ ions is carried out at 5 kV at a total current rating of 10 mA and a pressure of 2×10⁻⁷ mbar on an area that is 2×2 mm² in size.

Data were collected and processed with use being made of CasaXPS software and a Gauss function for the fitting procedure. The background noise is eliminated according to the Shirley method.

### 5.2 UV-Vis Spectroscopy (Ultraviolet Visible)

The optical transparency of the Ho-coated cover glasses is determined by measuring the transmission of light to a UV-2450 spectrophotometer by Shimadzu. Transmission spectra in the range of ultraviolet and visible wavelengths (200-850 nm) are created. Therein, the resolution is 1 nm. In order to eliminate the background noise effect, the baseline value was determined prior to the measurements on the samples (coated substrates).

### 5.3 Measurements of the Water Contact Angle (CA)

In order to examine the wetting properties, the contact angle of water is determined on the sample surfaces, using an OCA40 contact angle goniometer by DataPhysics Instruments GmbH. The method of the “sessile drop” is used both for static and dynamic measurements of the contact angle. After 24 of pure water (Millipore) have been applied through a needle at a dosing rate of 0.5 μL/sec, the worktable is lifted until the sample surface contacts the bottom side of the drop. The static contact angles are recorded after a balance of solid, liquid and gaseous phases has established.

In order to measure the dynamic contact angles, use is made of the “sessile drop needle-in method” wherein the needle is introduced to the center of the drop that is resting on the surface. A video is taken with a CCD camera while the drop size initially is increased until 84 have been released above the needle; thereafter, the drop size is reduced. The increase rate and the reduction rate are kept at a constant value of 0.5 μL/sec. The recorded video is used to derive graphical diagrams of the contact angle and the basic diameter of the drop across time. A plateau in the contact angle diagram indicates the advance angle in parallel with the increase in the basic diameter with rising drop volume. When the water is sucked back into the needle, the drop initially remains lodged. The angle that is measured as soon as the basic diameter declines is referred to as retraction angle.

In order to keep the adsorption of contaminants from the air at as low a level as possible, samples, which are also referred to as substrates, that still comprise active surfaces are kept in a desiccator filled with oxygen, after the deposition and the treatment processes have been completed. At least 3 measurements are taken for each sample in order to secure the expressiveness of the results.

### 5.4 Water Nucleation

The nucleation and the freezing behavior of supercooled water are observed through a CCD camera. A thermostatic chamber, a temperature control unit, a fluid pump and a cooling coolant circulator are used for this examination. The table with the sample mounted thereon is cooled to 5° C. using a Peltier element. The heat generated by the Peltier element is discharged by repumping a glycol-based coolant the temperature of which is kept at approximately 0° C. 3 μL of pure water are administered onto the cooled sample surface, while the table is cooled down further to −20° C. The temperature of the air above the sample is monitored by a temperature sensor and remains below 8° C. while a temperature of −20° C. is reached at the chamber bottom. The influence of moisture or condensate is kept at as low a level as possible by flushing with nitrogen.

### 5.5 Ice Adhesion

The ice adhesion test is carried out using a self-built device. An ice chamber comprises Peltier elements on the chamber bottom, while a refrigeration element is placed to two of the lateral walls. The ambient temperature in the refrigeration element is kept at approximately 10° C. There is a water cooling unit to discharge the heat generated by the Peltier elements which keep the temperature inside the ice chamber below 5° C. Once the sample has been locked in position on the chamber bottom using double-faced adhesive tape, 5 μL of pure water are administered onto the sample surface through a vertically applied needle. The ice chamber is further cooled down to −18° C. After the water drop has frozen and the needle tip has reached a temperature below −5° C., the needle is moved up at 0.2 mm/sec and pulls the ice off the surface while the force meter registers a peak in the force-time diagram. The height of the peak is interpreted to be the adhesion or cohesion force F, depending on the type of break.

Pictures are taken of the break. The true diameter of the broken surface of the ice is obtained after measurements using ImageJ software and calibration with the needle diameter (1.65 mm) The cross-sectional area A is calculated, with the ice adhesion force resulting as the force F per unit area A.

### 6. Results

### 6.1 UV-VIS Spectra

The transmission of visible light and ultraviolet radiation through cover glass samples result in transmission spectra. The spectra of Ho-coated cover glasses show a weakening of the radiation intensity with rising deposition thickness. With approximately 60 nm Ho, a transmission of approximately 5% is measured in the range of visible light. After thermal oxidation of the Ho layer having the same thickness at 400° C., 70% of the radiation intensity are measured in the range of visible light after the passage through the sample. This value rises to 80% after thermal oxidation at 700° C.

When the sample is treated in a continuous oxygen flow, a transparency that is 5% lower is measured for thermally oxidized samples at the same temperature. In analogy to the increased transparency with rising treatment temperature, a lower treatment temperature results in less transparent samples. The introduction of an intermediate titanium layer increases the opacity. The yellowish-transparent holmium oxide layer that is obtained by wet oxidation at a low temperature (300° C.) transmits more light in the range of higher wavelengths (700-750 nm).

### 6.2 XPS Spectra

In order to determine the change in the chemical composition of the Ho layer after the treatment, XPS spectra are created for the samples “as deposited” and “after treatment”.

A preliminary analysis shows spectra of O 1s and Ho 4d. Two distinct O 1s peaks at 529 eV and 531 eV can be recognized in the non-represented spectra. The intensity of the first peak at a higher binding energy declines with rising treatment temperature in the oven, while the second peak rises at a lower binding energy. In general, more than 20 atomic percent C are detected on the surface of all samples with deposited Ho at ˜289 eV, ˜288 eV, ˜286 eV and 284.6 eV. The highest carbon peak is observed at 284.6 eV and alone accounts for >10 atomic percent of C. After the MW plasma treatment has been completed, the Ho layer consists of an exceptionally high percentage F (more than 30 atomic percent). This can perhaps be attributed to fluoride radicals which are introduced by sealing the reactor at high power values.

Furthermore, Table 6 also shows the atomic percentages of C and 0 which are detected on the surface of the further analyzed samples. Therein, oxygen peaks can be observed at higher binding energies. In order to separate the oxygen content which can be attributed to organic substances caused by the contamination of the surface, a sputter analysis is made.

TABLE 6

| | Element composition [at. %] | | | | | |
|---|---|---|---|---|---|---|
| | | O | | | | |
| | | at | at | at | at | |
| | | −529 | −531 | −532 | −537 | Ho |
| Ho layer | C total | eV | eV | eV | eV | total |
| As deposited | 24.4 | 5.0 | 37.3 | 4.1 | — | 28.5 |
| RF plasma treatment | 28.0 | 4.7 | 31.8 | 6.3 | 3.2 | 25.3 |
| (RT) | | | | | | |
| Oven 100° C. - 24 h (wet) | 22.5 | 5.8 | 36.0 | 5.1 | — | 30.1 |
| Oven 500° C. - 30 min | 24.2 | 17.2 | 18.7 | 5.0 | — | 34.8 |

In an in-depth analysis, a Ho layer deposited on Si wafers is sputtered with argon and the element composition is determined at different intervals. After a sputter time of 1 min has elapsed, the C level decreases below the detection limit, indicating the elimination of the contamination of the surface. The O 1s peak at ˜532 eV decreases from 41.4 at. % to 3 at. %, while the peak at ˜529 eV increases from 5 at. % to 34.1 at. %. Two successive analyses with 1-minute increments resulted in a similar intensity for both O 1s peaks. This indicates the presence of native holmium oxide in the deposited holmium layer. It could, therefore, be concluded that the O 1s peak at ˜529 eV is derived from the native holmium oxide and organic surface contaminants are responsible for the oxygen peak(s) at higher binding energies (BE).

The Ho composition rises with increasing depth position of the layer while the O composition decreases until 2-3 atomic percent of O remain. The interface between the Si substrate and the Ho layer on which both Si and Ho can be detected is reached after 18 minutes of etching.

### 6.3 Water Contact Angle

Water contact angles (CA) on blank substrates are measured as reference points; they are shown in Table 7 together with a few typical values from literature. Due to variations in the material composition of glasses (microscope holders and cover glasses) as well as the crystallinity and the crystal orientation (in the case of Si wafers), the samples can be different from the samples used in literature for determining the contact angle. The handling of the samples also has an influence on the expressiveness to a considerable degree because contact angles can vary depending on the cleaning agent.

TABLE 7

Sessile drop contact angle [°]

| Blank substrates | Measured value | Value in literature |
|---|---|---|
| Object slide | 36.0 ± 2.7 | — |
| Cover glass | 60.0 ± 4.5 | 51.05 ± 0.84 |
| PC | 98.8 ± 3.3 | 82 |
| Si wafer | 44.5 ± 2.0 | 44.8 ± 1.7 ⁹⁵ |

In order to ensure consistent handling of the samples, the surfaces of successive samples are blown off using compressed N2, and the “ageing” of the samples is taken into account in the results analysis. Table 8 shows the contact angles on all Si wafers with Ho deposition using different follow-up treatment methods and parameters.

TABLE 8

| | | Static sessile |
|---|---|---|
| | | drop contact angle [°] |
| | | (3 to 7 days after |
| | | treatment or |
| | Samples | deposition) |
| Si—Ho | As deposited | 66.5 ± 0.5 |
| | Freshly coated sample, immersed | 64.4 ± 1.1 |
| | in water for 4 days | |
| Si—Ho | 100° C. - 24 h | 71.0 ± 0.2 |
| Oxidized in | 100° C. - 24 h (wet) | 74.7 ± 1.2 |
| the oven | 300° C. - 30 min (cont. flow, wet) | 65.4 ± 0.4 |
| | 400° C. - 30 min (cont. flow) | 61.1 ± 3.4 |
| | 400° C. - 30 min | 62.7 ± 0.8 |
| | 500° C. - 30 min | 63.7 ± 2.2 |
| | 700° C. - 30 min | 58.3 ± 5.4 |
| Si—Ti—Ho | 100° C. - 24 h | 71.3 ± 0.9 |
| Oxidized in | 100° C. - 24 h (wet) | 75.3 ± 2.5 |
| the oven | 300° C. - 30 min (cont. flow, wet) | 47.0 ± 5.3 |
| | 400° C. - 30 min (cont. flow) | 61.9 ± 0.4 |
| | 400° C. - 30 min | 62.8 ± 0.2 |
| | 500° C. - 30 min | 71.1 ± 6.0 |
| | 700° C. - 30 min | 59.4 ± 4.4 |
| Si—Ho | MW plasma RT - 500 W | 62.5 ± 3.1 |
| Retreated in | HF plasma RT - 150 W | 61.9 ± 1.5 |
| plasma | ICP RT - 3500 W | 67.4 ± 0.6 |
| | ICP - 200° C. - 3500 W | 31.9 ± 0.4 |
| | ICP - 400° C. - 3500 W | 50.9 ± 0.2 |

Although the contact angles of all of the above samples are within the hydrophilic range, the contact angle with water measured in the Ho layers as deposited is 22° in excess of the uncoated Si wafer.

Comparable contact angle values are obtained for Ho-coated and Ti—Ho-coated samples which were subjected to thermal treatment under the same conditions. The highest contact angle value (˜75°) is obtained for the Si—Ho sample that has oxidized in an oxygen atmosphere with a high moisture content at 100° C. for 24 h.

The contact angle is measured in a desiccator filled with oxygen after a resting time of at least 3 days after the deposition or treatment.

Static and dynamic water contact angles were also measured on uncoated and Ho-coated stamped PU films; they are shown in Table 9.

TABLE 9

| | | Static sessile |
|---|---|---|
| PU films | | drop contact angle [°] |
| Uncoated | A4 | 108 ± 2 |
| | A5 | 94 ± 3 |
| | A6 | 87 ± 1 |
| Ho-coated | A4 | 123 ± 5 |
| | A5 | 108 ± 4 |
| | A6 | 101 ± 3 |

An increase of the static contact angle by approximately 15° and a decrease of CAH by up to 5° are measured on Ho-coated microstructured PU films as compared with uncoated films. Cylindrical patterns with finer structures and shorter spacing (A4) have wider contact angles.

### 6.4 Water Nucleation

This section describes the freezing behavior of water. Since the temperature in different parts of the ice chamber varies, the temperature profile influences the heat transmission which, in turn, influences the freezing process of the water drop. Once the chamber bottom reaches −20° C., the temperature of the air in the center of the chamber is measured to be approximately 8° C. The chamber bottom temperature at which the drop freezes and the time elapsing from the start of nucleation to full freezing of the drop (freezing time) are shown in Table 10.

TABLE 10

| | | | Freezing |
|---|---|---|---|
| | | t_{freezing end}- | temperature |
| | Samples | t_{nucleation start} [S] | [° C.] |
| Si | Uncoated | 1.6 ± 0.1 | −20 |
| Si—Ho | As deposited | 4.0 ± 0.4 | −6 |
| | Oven 500° C. - 30 min | 5.5 ± 1.4 | −7 |
| | ICP - 200° C. - 3500 W | 2.2 ± 0.2 | −12 |
| PU film A4 | Uncoated | 31.2 ± 0.6 | −20 |

| | |
|---|---|
| Ho-deposited | No nucleation and freezing |
| | can be observed after >10 |
| | min at −20° C. |

The transparent supercooled water at the start of nucleation was semi-opaque and, subsequently, became increasingly opaque with progressing nucleus growth. The uppermost part of the drop is the hottest area. There, a tip forms once the drop has completely frozen. The freezing front which moves from the lower part to the upper part of the drop could be recognized. Furthermore, a decrease of the water contact angle could be observed at sub-zero temperatures.

Whereas water on a Ho-coated Si wafer starts freezing before the chamber bottom has reached −20° C., the drop in the fresh sample on a blank Si wafer is preserved down to −20° C.; thereafter, the drop freezes quickly. At a higher temperature, the freezing time with Si wafers with Ho deposition and with retreated Si wafers was longer.

The freezing of a drop on the microstructured PU film A4 starts at −20° C. and takes place within half a minute. If provided with a Ho layer, the PU film shows an exceptionally long delay in freezing.

### 6.5 Ice Adhesion

In order to test the freezing protection properties of the samples, the force required for vertical removal of the frozen drop is measured. After the diameter of the broken ice surface has been measured, the ice adhesion strength is calculated; it is shown in Table 11.

TABLE 11

| | | Ice adhesion strength/ | |
|---|---|---|---|
| | Samples | separation strength | Break type |
| Si | Uncoated | 1.3 ± 0.4 MPa | Cohesive |
| | | | break |
| Si—Ho | As deposited | 1.0 ± 0.2 MPa | Cohesive |
| | | | break |
| | Oven 500° C. - 30 min | 1.2 ± 0.5 MPa | Cohesive |
| | | | break |
| | ICP - 200° C. - 3500 W | 1.1 ± 0.1 MPa | Cohesive |
| | | | break |
| PU film A4 | Uncoated | 210 ± 30 kPa | Adhesive |
| | | | break |
| | Ho-deposited | 110 ± 20 kPa | Adhesive |
| | | | break |

If the break is cohesive, the ice remains attached to the sample surface, and the defect occurs in the ice itself, which is indicative of a strong ice adhesion. On the other hand, an adhesive break occurs on the interface between ice and sample surface and, in addition, shows frost formation on originally dry surfaces after contact with sub-zero temperatures for >10 min

While all Si samples show a cohesive break with a separating strength of more than 1 MPa, the low adhesion strengths that were obtained for the PU film A4 indicate that ice can be easily removed. This is even strengthened by the presence of a Ho layer which reduces the adhesion strength by approximately 50%.

1. A body, comprising an anti-icing coating on a surface of the body, wherein the anti-icing coating has a thickness of up to 500 nm and comprises at least one rare earth metal oxide.

2. The body according to claim 1, wherein the anti-icing coating comprises a structuring of elevations in the form of a dot or a line pattern having a spacing of from 1 to 1000 micrometers between elevations.

3. The body according to claim 1, wherein the anti-icing coating
a) contains 15 to 45 atomic percent of a rare earth metal and
b) 30 to 80 atomic percent of oxygen
wherein each is determined according to an XPS analysis and in relation to the total atomic percentage of the anti-icing coating.

4. The body according to claim 1, wherein the anti-icing coating is produced by means of a cathode sputtering process.

5. The body according to claim 1, wherein the anti-icing coating is produced by means of a low-pressure plasma process.

6. The body according to claim 1, wherein the anti-icing coating is produced by means of a sol-gel plasma process.

7. An anti-icing coating having a thickness of up to 500 nm, wherein the anti-icing coating comprises at least one rare earth metal oxide.

8. A method for producing an anti-icing coating on the surface of a body, comprising applying to the surface of the body a composition comprising at least one rare earth metal oxide using a surface coating process.

9. The method according to claim 8, wherein the anti-icing coating comprises
a) 15 to 45 atomic percent of at least one rare earth metal and
b) 30 to 80 atomic percent of oxygen
wherein each is determined according to XPS analysis and in relation to the total atomic percentage of the anti-icing coating.

10. The method according to claim 8, wherein the composition comprises a) at least one rare earth metal and b) oxygen to prevent the formation of ice on at least one surface of a body.

11. The method according to claim 8, wherein the composition comprises a) at least one rare earth metal and b) oxygen to reduce the force of ice adhesion to at least one surface of a body.

12. The method according to claim 8, wherein the composition comprises a) at least one rare earth metal and b) oxygen to lower the freezing point of a liquid substance adhering to at least one surface of a body.

13. The method according to claim 8, wherein the composition comprises a) at least one rare earth metal and b) oxygen to slow down the freezing process of a liquid substance adhering to at least one surface of a body.

14. The body according to claim 1, wherein the anti-icing coating applied has a thickness of 10 to 500 nm.

15. The body according to claim 1, wherein the anti-icing coating applied has a thickness of 10 to 195 nm.

16. The body according to claim 2, wherein the elevations in the form of a dot or line form recesses between the elevations, wherein the recesses have a dimension of from 1 to 1000 micrometers.

17. The body according to claim 1, wherein the elevations in the form of a dot or line pattern have spacings between the elevations of from 0.01 to 800 nanometers.

18. The body according to claim 17, wherein the elevations in the form of a dot or line form recesses between the elevations, wherein the recesses have a dimension of from 0.01 to 800 nanometers.
